(19) United States
(12) Patent Application Publication
(10) Pub. No.: US 2024/0288523 A1
(43) Pub. Date: Aug. 29, 2024

(54) OUT OF DISTRIBUTION TESTING FOR MAGNETIC RESONANCE IMAGING

(71) Applicant: KONINKLIJKE PHILIPS N.V., EINDHOVEN (NL)

(72) Inventors: Sergey Kastryulin, Moscow (RU); Artyon Tsanda, Hamburg (DE); Nicola Pezzotti, Eindhoven (NL)

(21) Appl. No.: 18/570,672

(22) PCT Filed: Jun. 22, 2022
(86) PCT No.: PCT/EP2022/066947

§ 371 Date: Dec. 15, 2023

(30) Foreign Application Priority Data
Jun. 24, 2021 (RU) 2021118466

(51) Int. Cl. G01R 33/56; G01R 33/48; G06T 11/00

(52) U.S. Cl. CPC G01R 33/5608; G01R 33/4818; G06T 11/005; G06T 11/006; G06T 2210/41; G06T 2211/424; G06T 2211/441

(57) ABSTRACT

Disclosed herein is a medical system (100, 300) comprising a memory (110) storing machine executable instructions (120). The medical system further comprises a computational system (104). Execution of the machine executable instructions causes the computational system to: reconstruct or receive (202) a test magnetic resonance image reconstructed from undersampled k-space data; receive (204) a test signal in response to inputting the test magnetic resonance image into an out of distribution testing neural network; and provide (206) the test signal. The test neural network is configured for outputting the test signal in response to receiving the test magnetic resonance image. The test signal is descriptive if the test magnetic resonance image is within a training distribution defined by a set of training data.

### FIELD OF THE INVENTION

The invention relates to magnetic resonance imaging, in particular to compressed sensing in magnetic resonance imaging.

### BACKGROUND OF THE INVENTION

A large static magnetic field is used by Magnetic Resonance Imaging (MRI) scanners to align the nuclear spins of atoms as part of the procedure for producing images within the body of a patient. This large static magnetic field is referred to as the BO field or the main magnetic field. Various quantities or properties of the subject can be measured spatially and imaged using MRI. Compressed sensing (CS) is one means of reducing the time required to acquire the k-space data for a magnetic resonance image. Medical images can typically be compressed or have a sparse representation. The idea behind compressed sensing is that because the medical image can have a sparse representation it is possible to acquire and reconstruct the image by sampling less k-space data than is required by the Nyquist criterion (herein referred to an undersampled k-space data). To do this, the k-space data is sampled so that the artifacts due to under sampling appear in image space as random noise.

To reconstruct the image an iterative process is typically used. First, the image is reconstructed from the acquired or measured k-space data. In conventional CS a filter module transforms the image into to a sparse representation, such as a wavelet representation. The transformed image is then thresholded to remove noise and typically changed back to image space to produce a de-noised image. A data consistency module to ensure consistence with the measured k-space data is then used to refine the image. The data consistency module takes the de-noised image and adjusts it so that the k-space transform of the image is more consistent with the measured k-space data. The effect of this is that the noise due to the under sampling is reduced. The image can then be improved by iteratively processing the image with the filter module and the data consistency module. United States patent application US 20170372155A discloses the image quality scoring of an image from a medical scanner, a generative model of an expected good quality image may be created using deep machine-learning. The deviation of an input image from the generative model is used as an input feature vector for a discriminative model. The discriminative model may also operate on another input feature vector derived from the input image. Based on these input feature vectors, the discriminative model outputs an image quality score.

### SUMMARY OF THE INVENTION

The invention provides for a medical system, a computer program and a method in the independent claims. Embodiments are given in the dependent claims.

There exist different ways of implementing CS algorithms. Various elements or even the entire numerical CS scheme described above may be replaced with trained neural networks. A problem with using neural networks is that when they are presented with data that is within their training distribution (data that is similar to which was used to train the neural network) they provide very good results. If data is presented to a neural network that is outside of its training distribution, then the results produced by the neural network can be incorrect. This could for example lead to the reconstruction of incorrect magnetic resonance images or to a failure of the reconstruction algorithm.

Even with modern computer a CS algorithm can be time consuming for large amounts of k-space data. Embodiments may provide a means of either rating how accurate a reconstructed image will be before it is reconstructed or provide an estimate of how well the CS reconstruction will work before it is performed. This may for example lead to more confidence in the resulting images and may also be used to avoid the reconstruction CS images when the algorithm is likely to fail or perform poorly.

To achieve this the undersampled k-space data is first reconstructed into a test magnetic resonance image, for example by Fourier transforming it. This will lead to an image with noise and artifacts. However, an insight disclosed herein is that the noise and the artifacts in the test image can be used to identify if the undersampled k-space data belongs to a training distribution or not. A particular training distribution will result in noise and image artifacts which can be used by an out of distribution testing neural network (an image classification neural network) to provide a test signal which describes if the test magnetic resonance image is within a training distribution defined by a set of training data.

In an embodiment of this, the out of distribution testing neural network is trained as a discriminator in a generative adaptative neural network. Out of distribution testing neural networks trained in this way are particularly effective at performing Out Of Distribution (OOD) testing.

In one aspect the invention provides for a medical system that comprises a memory that stores machine executable instructions. The memory could possibly also store an out of distribution testing neural network or the out of distribution testing neural network could be located on a remote or virtual (cloud-based computing system). The out of distribution testing neural network is a neural network. The out of distribution testing neural network may be a classifier network that is configured for receiving an image and providing a classification of this image. The test neural network is configured for outputting a test signal in response to receiving a test magnetic resonance image. The test signal is descriptive if the test magnetic resonance image is within a training distribution defined by a set of training data. The set of training data may be data that is used to provide training such as deep learning for a neural network or a collection of neural networks.

The test signal may take different forms in different examples. In one example the test signal is a binary classification or indication of a particular classification. For example, a 1 may indicate that the test magnetic resonance image is within the training distribution. In the same example the 0 may indicate that the test magnetic resonance image is outside of the training distribution. In other examples the test signal may be a probability that indicates that the test magnetic resonance image is within the training distribution. As both examples may for example be used as an indicator or a level of confidence that the test magnetic resonance image is within the training distribution.

The medical system further comprises a computational system. The references to ‘computational system’ herein are intended to represent one or more computing or computational devices at one or more locations. For example, portions of the computational system may be at different locations and/or may be available as a remote computational system or a cloud based computational system. Portions of the computational system by be available online on a on demand basis provided by virtual machines.

Execution of the machine-executable instructions causes the computational system to optionally receive undersampled k-space data descriptive of a region of interest of a subject. The label ‘undersampled k-space data’ is a name to indicate particular k-space data. The k-space data is the data sampled by a magnetic resonance imaging system when imaging the region of interest of the subject. Undersampled k-space data refers to k-space data that does not fulfill the Nyquist criterion. It is however still possible to reconstruct images using an image reconstruction technique such as compressed sensing.

Execution of the machine-executable instructions further causes the computational system to request or cause a reconstruction the test magnetic resonance image from the undersampled k-space data. This reconstruction could be performed by the computational system or it could be a reconstruction performed on a remote or cloud-based computing system. This reconstruction may for example be using an analytical algorithm that performs Fourier transforms on the k-space data. If the undersampled k-space data is reconstructed using a Fourier transform it may have noise in it, particularly if it is undersampled. Execution of the machine-executable instructions further causes the computational system to receive the test signal in response to inputting the test magnetic resonance image into the out of distribution testing neural network as input. Execution of the machine-executable instructions further causes the computational system to provide the test signal.

This embodiment may be beneficial because the out of distribution testing neural network tests an image that has been reconstructed from the undersampled k-space data. Because the undersampled k-space data is undersampled there will be image artifacts present in the test magnetic resonance image. The out of distribution testing neural network may be configured to recognize the artifacts in the test magnetic resonance image and tell from the artifacts in the image whether or not the undersampled k-space data is within the training distribution or covered by the training distribution. The test signal may for example be used for other control elements in a program or it may also be provided with a further reconstruction of the undersampled k-space data, for example using a compressed sensing reconstruction. The test signal can also be used to determine if it is worthwhile performing a numerically intensive reconstruction of the undersampled k-space data before it is undertaken. The testing of the test magnetic resonance image is extremely efficient because as it is in image space the out of distribution testing neural network has not been trained for looking at particular locations in k-space. For example, a neural network could be trained to evaluate the undersampled k-space data directly but it would need to be trained for the particular k-space sampling pattern. In this example, the undersampled k-space data is converted into an image and then because it is already in image space, the out of distribution testing neural network is essentially able to take images of the correct size or format. This means that the out of distribution testing neural network is to a large degree independent of the particular sampling pattern that was used to acquire the undersampled k-space data. This may enable a flexible change or adjustment of the k-space sampling pattern.

In another embodiment execution of the machine-executable instructions further causes the computational system to receive a clinical magnetic resonance image reconstructed from the undersampled k-space data according to a compressed sensing magnetic resonance imaging reconstruction algorithm if the test signal indicates that the test magnetic resonance image is within the training distribution. This reconstruction of the clinical magnetic resonance image could be performed by the computational system or the computational system could send the under sampled k-space data to remote or cloud based computing system to perform the reconstruction.

In this embodiment the reconstruction of the clinical magnetic resonance image from the undersampled k-space data is conditional on the test signal. This may be used to avoid a lengthy reconstruction of the clinical magnetic resonance image when the data has problems.

This may also enable the operator of a medical imaging system such as a magnetic resonance imaging system to detect if the undersampled k-space data will likely result in a good quality clinical magnetic resonance image or not before the lengthy image reconstruction has taken place. This may for example enable more data or a reacquisition of data while the subject is still in the clinic.

In another embodiment the compressed sensing magnetic resonance imaging reconstruction algorithm is configured for causing the reconstruction of the clinical magnetic resonance image iteratively using an image processing neural network. This may be performed by the computational system or it may request the reconstruction from a remote or cloud based computing system. The image processing neural network may take different forms in different examples. For example, the compressed sensing algorithms typically used for reconstructing magnetic resonance images are formulated as analytical algorithms that process the data and perform data consistency iteratively. At each iteration an intermediate image may be reconstructed. Often times a filter, such as a denoising filter, is used to process this image before the data consistency step. The image processing neural network may for example be a denoising filter.

In another embodiment the image processing neural network is trained using the set of training date. This embodiment is particularly beneficial because the test signal can be used to evaluate how effective the image processing neural network that is used within the compressed sensing magnetic resonance imaging reconstruction algorithm will be. This for example can be used for a confidence score or it can be used to control whether the compressed sensing magnetic resonance imaging reconstruction algorithm is actually used or if additional data or if an additional algorithm is used.

In another embodiment the image processing neural network is configured as a denoising filter for denoising an intermediate image between each iteration. This is each iteration of the compressed sensing magnetic resonance imaging reconstruction algorithm.

In another embodiment the image processing neural network functions as an image compression algorithm. As described above, in compressed sensing there may be a sparsifying transform that is used in combination with a thresholding and the inversion of the sparsification. In combination, these operations function formally as a compression algorithm and is a theoretical foundation of the compressed sensing theory. Stating that the image processing neural network functions as an image compression algorithm states that it is used for one or more of the sparsifying transform, the thresholding and the inverse sparsification. For example, a neural network could be trained to perform all of these tasks simultaneously. In another embodiment this image compression algorithm is also trained using the set of training data. For training the image processing neural network fully sampled k-space data can be acquired. The training images can then be reconstructed by using the fully sampled k-space data. This provides a reference to the output of the neural network when training. The undersampled k-space data can be simulated by taking the fully simulated k-space data and removing a portion of it so that it is now undersampled. The undersampled k-space data can be paired with the images reconstructed from the fully sampled k-space data and can be used as training data in a variety of situations for a variety of types of neural networks.

In another embodiment the compressed sensing magnetic resonance imaging reconstruction algorithm is a numerical image reconstruction algorithm that is configured for finding solutions to undeterminable linear systems descriptive of a reconstruction of the clinical magnetic resonance image from the undersampled k-space data. In this embodiment, the compressed sensing magnetic resonance imaging reconstruction algorithm does not use a neural network: it is a conventional compressed sensing reconstruction algorithm. This embodiment may be beneficial because although the training data was not used to train a portion of the compressed sensing reconstruction algorithm, the out of distribution testing neural network can still be used to detect undersampled k-space data that is deficient. For example, the set of training data could still be constructed from fully sampled k-space data that is used to generate training output images and make synthetic undersampled k-space data. This could then be used to train the out of distribution testing neural network. If there was a problem with the undersampled k-space data after as it was measured, such as the subject moving or other event which would corrupt the quality of the undersampled k-space data, the out of distribution testing neural network would still detect it.

In another embodiment the compressed sensing magnetic resonance imaging reconstruction algorithm comprises an image reconstruction neural network configured for reconstructing the clinical magnetic resonance image from the undersampled k-space data at each stage of an iterative compressed sensing algorithm. In this example, instead of using a conventional reconstruction such as a Fourier transform or an algorithmic sparse transform, there is an image reconstruction neural network that performs this task. Again, the image reconstruction neural network could be trained by constructing training data from fully sampled k-space data. The images used for training the image reconstruction neural network would be images obtained from reconstruction of the fully sampled k-space data using an analytical algorithm and then synthetic undersampled k-space data could be obtained by taking the fully sampled k-space data and deleting part of the samples.

The image reconstruction neural network in this example could be iterative or it could be a single pass reconstruction algorithm.

In another embodiment the out of distribution testing neural network is trained as a discriminator neural network in a generative adversarial network using the training data. In a generative adversarial network, there is a generator neural network and a discriminator neural network. The generator and discriminator are trained together. The discriminator neural network is trained to generate artificial input to the generative adversarial network. The generative adversarial network is trained using the combination of this fake data from the generator and also correct or real data. The benefit of training the out of distribution testing neural network in a generative adversarial network is that it becomes extremely good at detecting if the test magnetic resonance image represents an image for the training distribution or not.

In another embodiment the generative adversarial network comprises a generative neural network configured for generating simulated images in response to receiving a noise distribution. In this example a vector or other noise is input into the generative neural network which is used to produce the simulated images. The simulated images and the training data are then used to train the out of distribution testing neural network.

In another embodiment the generative adversarial network comprises a generative neural network configured for generating simulated images in response to receiving a simulated test image. For example, instead of using a noise vector to be put into the generated simulated images, undersampled k-space data could for example be input into the generative neural network. This may have the advantage of making the out of distribution testing neural network function more robustly and more accurately.

In another embodiment the test magnetic resonance image is reconstructed from the undersampled k-space data using a single Fourier transform. This embodiment has the advantage that when the undersampled k-space data is reconstructed using a single Fourier transform it contains image artifacts. These image artifacts are then able to be detected by the out of distribution testing neural network and/or what it uses to evaluate if the undersampled k-space data is within the training distribution or not.

In another embodiment the undersampled k-space data is parallel imaging k-space data collected for a set of reference coils. The computational system is configured for reconstructing a coil image for each of the set of receive coil images using the single Fourier transform. The test magnetic resonance image is reconstructed by combining the coil image for each of the set of receive coils using a set of coil sensitivity maps. This embodiment is also beneficial because the individual images for each of the coils will also have artifacts. Each out of distribution testing neural network will then be able to test the k-space data from all the set of receive coils simultaneously by testing the test magnetic resonance image.

In another embodiment, the memory further contains pulse sequence commands configured to control a magnetic resonance imaging system to acquire the undersampled k-space data from the region of interest. Execution of the machine-executable instructions further causes the computational system to acquire the undersampled k-space data by controlling the magnetic resonance imaging system with the pulse sequence commands.

In another embodiment the medical system further comprises a magnetic resonance imaging system.

In another embodiment execution of the machine-executable instructions further causes the computational system to provide a warning if the test signal indicates that the test magnetic resonance imaging is outside of the training distribution. This could be a warning that is provided using a user interface of a computer or it may be provided using other audio, visual or tactile means.

In another embodiment execution of the machine-executable instructions further causes the computational system to request a reacquisition of the undersampled k-space data if the test signal indicates that the test magnetic resonance image is outside of the training distribution. This portion could for example be implemented into the control of a magnetic resonance imaging system and this may enable the operator to reacquire the undersampled k-space data immediately if this is detected.

In another embodiment execution of the machine-executable instructions further causes a reconstruction of the clinical magnetic resonance image using a purely numerical reconstruction algorithm if the test signal indicates that the test magnetic resonance image is outside of the training distribution. This reconstruction could be performed by the computational system or a remote or cloud based computational system. For example, if the neural network is used in the compressed sensing reconstruction a failure indicated by the test signal could avoid the use of the algorithm that uses the neural network. So essentially, in this embodiment, the test signal is used to select an alternative reconstruction of the clinical magnetic resonance image.

In another embodiment execution of the machine-executable instructions further causes the computational system to control the magnetic resonance imaging system to continue acquisition of the undersampled k-space data and repeat the steps of receiving the undersampled k-space data descriptive of a region of interest of a subject, reconstructing the test magnetic resonance image from the undersampled k-space data and receiving the test signal in response to inputting the test magnetic resonance image into the out of distribution testing neural network if the test magnetic resonance image is outside of the training distribution. In this example the out of distribution testing neural network is used to check if enough k-space data has been acquired. For example, if the quality of the test magnetic resonance image has too many artifacts, then the system can be controlled to acquire yet more k-space data. This can be done repeatedly and the process can be stopped once the test signal indicates that the magnetic resonance imaging is within the training distribution. In another embodiment the training data comprises artifact-free magnetic resonance images reconstructed from fully sampled k-space data and simulated undersampled k-space data reconstructed from the fully sampled k-space data. This data may for example be used for training the neural networks used in reconstructing or the medical image or within the compressed sensing algorithm.

In another embodiment the training data for the out of distribution testing neural network comprises simulated undersampled k-space data constructed from fully sampled k-space data and from simulated test magnetic resonance images reconstructed from the simulated undersampled k-space data. The simulated undersampled k-space data and the simulated undersampled k-space data can for example be used to train the out of distribution testing neural network directly using deep learning or as part of a generative adaptive network as was described above. In this case, images reconstructed from the fully sampled k-space data would additionally be used for training also. In another aspect, the invention provides for a method of operating a medical system.

The method comprises optionally receiving undersampled k-space data descriptive of a region of interest of the subject. The method further comprises receiving a test magnetic resonance image reconstructed from the undersampled k-space data. The method further comprises receiving the test signal in response to inputting the test magnetic resonance image into an out of distribution testing neural network. The test neural network is configured for outputting a test signal in response to receiving a test magnetic resonance image. The test signal is descriptive if the test magnetic resonance image is within a training distribution defined by the set of training data. The method further comprises providing the test signal.

In another embodiment the out of distribution training neural network is trained as a discriminator neural network in a generative adversarial network using the training data.

In another aspect the invention provides for a computer program comprising machine-executable instructions for execution by a computational system.

Execution of the machine-executable instructions further causes the computational system to optionally receive undersampled k-space data descriptive of a region of interest of the subject. Execution of the machine-executable instructions further causes the computational system to reconstruct or receive the test magnetic resonance image from the undersampled k-space data. Execution of the machine-executable instructions further causes the computational system to receive the test signal in response to inputting the test magnetic resonance image into an out of distribution testing neural network. The out of distribution testing neural network is configured for outputting a test signal in response to receiving a test magnetic resonance image. The test signal is descriptive if the test magnetic resonance image is within a training distribution defined by a set of training data. Execution of the machine-executable instructions further causes the computational system to provide the test signal.

It is understood that one or more of the aforementioned embodiments of the invention may be combined as long as the combined embodiments are not mutually exclusive.

As will be appreciated by one skilled in the art, aspects of the present invention may be embodied as an apparatus, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit.” “module” or “system.” Furthermore, aspects of the present invention may take the form of a computer program product embodied in one or more computer readable medium(s) having computer executable code embodied thereon.

Any combination of one or more computer readable medium(s) may be utilized. The computer readable medium may be a computer readable signal medium or a computer readable storage medium. A ‘computer-readable storage medium’ as used herein encompasses any tangible storage medium which may store instructions which are executable by a processor or computational system of a computing device. The computer-readable storage medium may be referred to as a computer-readable non-transitory storage medium. The computer-readable storage medium may also be referred to as a tangible computer readable medium. In some embodiments, a computer-readable storage medium may also be able to store data which is able to be accessed by the computational system of the computing device. Examples of computer-readable storage media include, but are not limited to: a floppy disk, a magnetic hard disk drive, a solid-state hard disk, flash memory, a USB thumb drive. Random Access Memory (RAM). Read Only Memory (ROM), an optical disk, a magneto-optical disk, and the register file of the computational system. Examples of optical disks include Compact Disks (CD) and Digital Versatile Disks (DVD), for example CD-ROM. CD-RW. CD-R, DVD-ROM, DVD-RW, or DVD-R disks. The term computer readable-storage medium also refers to various types of recording media capable of being accessed by the computer device via a network or communication link. For example, data may be retrieved over a modem, over the internet, or over a local area network. Computer executable code embodied on a computer readable medium may be transmitted using any appropriate medium, including but not limited to wireless, wire line, optical fiber cable, RF, etc., or any suitable combination of the foregoing.

A computer readable signal medium may include a propagated data signal with computer executable code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

‘Computer memory’ or ‘memory’ is an example of a computer-readable storage medium. Computer memory is any memory which is directly accessible to a computational system. ‘Computer storage’ or ‘storage’ is a further example of a computer-readable storage medium. Computer storage is any non-volatile computer-readable storage medium. In some embodiments computer storage may also be computer memory or vice versa.

A ‘computational system’ as used herein encompasses an electronic component which is able to execute a program or machine executable instruction or computer executable code. References to the computational system comprising the example of “a computational system” should be interpreted as possibly containing more than one computational system or processing core. The computational system may for instance be a multi-core processor. A computational system may also refer to a collection of computational systems within a single computer system or distributed amongst multiple computer systems. The term computational system should also be interpreted to possibly refer to a collection or network of computing devices each comprising a processor or computational systems. The machine executable code or instructions may be executed by multiple computational systems or processors that may be within the same computing device or which may even be distributed across multiple computing devices.

Machine executable instructions or computer executable code may comprise instructions or a program which causes a processor or other computational system to perform an aspect of the present invention. Computer executable code for carrying out operations for aspects of the present invention may be written in any combination of one or more programming languages, including an object oriented programming language such as Java. Smalltalk. C++ or the like and conventional procedural programming languages, such as the “C” programming language or similar programming languages and compiled into machine executable instructions. In some instances, the computer executable code may be in the form of a high-level language or in a pre-compiled form and be used in conjunction with an interpreter which generates the machine executable instructions on the fly. In other instances, the machine executable instructions or computer executable code may be in the form of programming for programmable logic gate arrays.

The computer executable code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described with reference to flowchart illustrations and/or block diagrams of methods, apparatus (systems) and computer program products according to embodiments of the invention. It is understood that each block or a portion of the blocks of the flowchart, illustrations, and/or block diagrams, can be implemented by computer program instructions in form of computer executable code when applicable. It is further under stood that, when not mutually exclusive, combinations of blocks in different flowcharts, illustrations, and/or block diagrams may be combined. These computer program instructions may be provided to a computational system of a general purpose computer, special purpose computer, or other programmable data processing apparatus to produce a machine, such that the instructions, which execute via the computational system of the computer or other programmable data processing apparatus, create means for implementing the functions/acts specified in the flowchart and/or block diagram block or blocks.

These machine executable instructions or computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The machine executable instructions or computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

A ‘user interface’ as used herein is an interface which allows a user or operator to interact with a computer or computer system. A ‘user interface’ may also be referred to as a human interface device. A user interface may provide information or data to the operator and/or receive information or data from the operator. A user interface may enable input from an operator to be received by the computer and may provide output to the user from the computer. In other words, the user interface may allow an operator to control or manipulate a computer and the interface may allow the computer to indicate the effects of the operator's control or manipulation. The display of data or information on a display or a graphical user interface is an example of providing information to an operator. The receiving of data through a keyboard, mouse, trackball, touchpad, pointing stick, graphics tablet, joystick, gamepad, webcam, headset, pedals, wired glove, remote control, and accelerometer are all examples of user interface components which enable the receiving of information or data from an operator.

A ‘hardware interface’ as used herein encompasses an interface which enables the computational system of a computer system to interact with and/or control an external computing device and/or apparatus. A hardware interface may allow a computational system to send control signals or instructions to an external computing device and/or apparatus. A hardware interface may also enable a computational system to exchange data with an external computing device and/or apparatus. Examples of a hardware interface include, but are not limited to: a universal serial bus, IEEE 1394 port, parallel port, IEEE 1284 port, serial port, RS-232 port, IEEE-488 port, Bluetooth connection, Wireless local area network connection, TCP/IP connection, Ethernet connection, control voltage interface, MIDI interface, analog input interface, and digital input interface.

A ‘display’ or ‘display device’ as used herein encompasses an output device or a user interface adapted for displaying images or data. A display may output visual, audio, and or tactile data. Examples of a display include, but are not limited to: a computer monitor, a television screen, a touch screen, tactile electronic display, Braille screen,

Cathode ray tube (CRT), Storage tube, Bi-stable display, Electronic paper, Vector display, Flat panel display, Vacuum fluorescent display (VF), Light-emitting diode (LED) displays. Electroluminescent display (ELD), Plasma display panels (PDP), Liquid crystal display (LCD), Organic light-emitting diode displays (OLED), a projector, and Head-mounted display.

Medical imaging data is defined herein as being recorded measurements made by a tomographic medical imaging system descriptive of a subject. The medical imaging data may be reconstructed into a medical image. A medical image id defined herein as being the reconstructed two- or three-dimensional visualization of anatomic data contained within the medical imaging data. This visualization can be performed using a computer.

K-space data is defined herein as being the recorded measurements of radio frequency signals emitted by atomic spins using the antenna of a Magnetic resonance apparatus during a magnetic resonance imaging scan. Magnetic resonance data is an example of tomographic medical image data.

Undersampled k-space data is defined as k-space data that contains less k-space data than necessary to satisfy the Nyquist criterion.

A Magnetic Resonance Imaging (MRI) image or MR image is defined herein as being the reconstructed two- or three-dimensional visualization of anatomic data contained within the magnetic resonance imaging data. This visualization can be performed using a computer.

### BRIEF DESCRIPTION OF THE DRAWINGS

In the following preferred embodiments of the invention will be described, by way of example only, and with reference to the drawings in which:

FIG. 1 illustrates an example of a medical system;

FIG. 2 shows a flow chart which illustrates a method of using the medical system of FIG. 1;

FIG. 3 illustrates a further example of a medical system;

FIG. 4 shows a flow chart which illustrates a method of using the medical system of FIG. 3:

FIG. 5 illustrates an example of a generative adversarial network which can be used to train an out of distribution testing neural network;

FIG. 6 illustrates the use of an out of distribution testing neural network; and

FIG. 7 illustrates a further example of a generative adversarial network which can be used to train an out of distribution testing neural network.

### DESCRIPTION OF EMBODIMENTS

Like numbered elements in these figures are either equivalent elements or perform the same function. Elements which have been discussed previously will not necessarily be discussed in later figures if the function is equivalent.

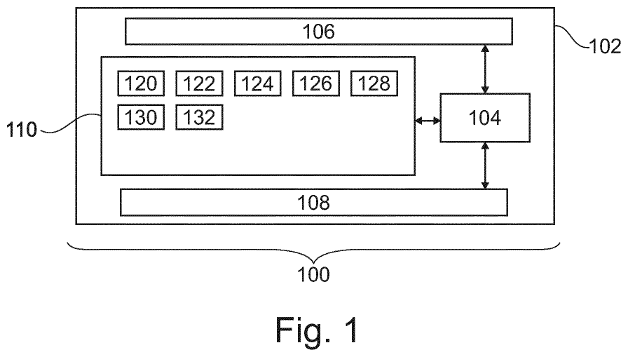

FIG. 1 illustrates an example of a medical system 100. The medical system is shown as comprising a computer 102. The computer 102 is intended to represent one or more computational or computing devices. The computer 102 could for example be integrated into a magnetic resonance imaging system as part of its control system. In other examples, the computer 102 could be a remote computer system used to reconstruct images remotely. For example, the computer 102 could be a server in a radiology department or it could be a virtual computer system located in a cloud computing system.

The computer 102 is further shown as comprising a computation system 104. The computational system 104 is intended to represent one or more processors or processing cores or other computational systems that are located at one or more locations. The computational system 104 is shown as being connected to an optional hardware interface 106. The optional hardware interface 106 may for example enable the computational system 104 to control other components such as a magnetic resonance imaging system.

The computational system 104 is further shown as being connected to an optional user interface 108 which may for example enable an operator to control and operate the medical system 100. The computational system 104 is further shown as being connected to a memory 110. The memory 110 is intended to represent different types of memory which could be connected to the computational system 104.

The memory is shown as containing machine-executable instructions 120. The machine-executable instructions 120 enable the computational system 104 to perform tasks such as controlling other components as well as performing various data and image processing tasks. The memory 110 is further shown as containing an out of distribution testing neural network 122. The out of distribution testing neural network 122 is configured for receiving a test magnetic resonance image 126 and in response, providing a test signal. As an alternative the out of distribution testing neural network could be located on a remote or cloud based computing system.

The memory 110 is further shown as containing k-space data 124. This is k-space data 124 that was acquired using a magnetic resonance imaging system. The memory 110 is further shown as containing a test magnetic resonance image 126 that was reconstructed from the k-space data 124. This for example may be done using a Fourier transform according to a magnetic resonance imaging protocol. The k-space data 124 is undersampled k-space data 124. By being undersampled it means that the k-space data does not fulfill the Nyquist criterion. When the undersampled k-space data 124 is reconstructed into the test magnetic resonance image 126 the test magnetic resonance image 126 will contain image artifacts such as distortions and noise caused by the undersampling. The out of distribution testing neural network 122 may for example be an image classification neural network. The out of distribution testing neural network 122 may be trained to recognize if the undersampled k-space data 124 is within a training distribution defined by a set of training data. The training data as used herein encompasses data which may be used for training a neural network. As such, the training data provides input for the neural network and a training output or training test signal which the output of the out of distribution testing neural network 122 can be compared against.

The memory 128 is further shown as containing a test signal 128 that was received in response to inputting the test magnetic resonance image 126 as input into the out of distribution testing neural network 122. The test signal 128 may be used to either indicate or provide a probability indicating whether the test magnetic resonance image 126 is within the training distribution.

The memory 110 is shown as containing optional compressed sensing magnetic resonance imaging reconstruction algorithm 130. This is an algorithm which is used to reconstruct a clinical magnetic resonance image 132 from the undersampled k-space data 124 according to a compressed sensing algorithm. The compressed sensing magnetic resonance imaging reconstruction algorithm 130 may be a conventional one that does not use any neural networks or there may be different types of neural networks incorporated into the compressed sensing magnetic resonance imaging reconstruction algorithm. In some examples the data used for training neural network components of the compressed sensing magnetic resonance imaging reconstruction algorithm 130 are trained using the same training distribution defined by the set of training data as was used for training the out of distribution testing neural network 122.

In some examples the out of distribution testing neural network 122 was trained in a GAN network. The out of distribution testing neural network 122 was the discriminator in the GAN network. Using the discriminator of the GAN network as the out of distribution testing neural network 122 may have the technical advantage that it is much more robust and much more effective at detecting if the undersampled k-space data 124 is within the training distribution.

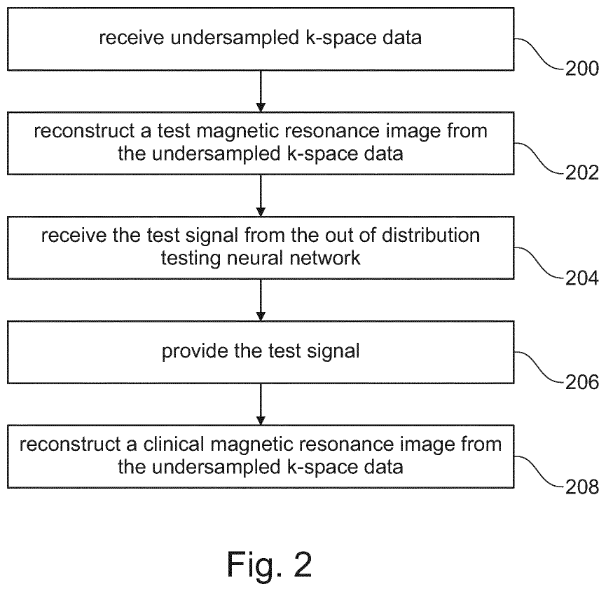

FIG. 2 shows a flowchart which illustrates a method of operating medical system 100 of FIG. 1. The method and system show steps being performed by the computational system 104. As an alternative the image reconstructions and/or the use of the out of distribution testing neural network could be performed on a remote or cloud based computational system, First, in step 200, the undersampled k-space data 124 is optionally received. The undersampled k-space data 124 is descriptive of a region of interest of a subject during a magnetic resonance imaging examination. Next, in step 202, the test magnetic resonance image 126 is reconstructed from the undersampled k-space data 124 or the test magnetic resonance image 126 is received already reconstructed. The reconstruction may be performed using a Fourier transform. Next, in step 204, the test signal 128 is received in response to inputting the test magnetic resonance image 126 as input into the out of distribution testing neural network 122. Then, in step 206, the test signal 128 is provided. This may be used for a variety of purposes. For example, the test signal 128 in some examples may be a probability. In this case, the test signal could be used as something analogous to a confidence measure. The test signal may therefore be appended to data or meta data descriptive of a later clinical magnetic resonance image 132. In other examples the test signal 128 can be used to control the behavior of the reconstruction and/or the magnetic resonance imaging. For example, if the test signal 128 indicates that the undersampled k-space data 124 is not within the training distribution, then it may be beneficial to use a different reconstruction algorithm or to reacquire or acquire more undersampled k-space data 124.

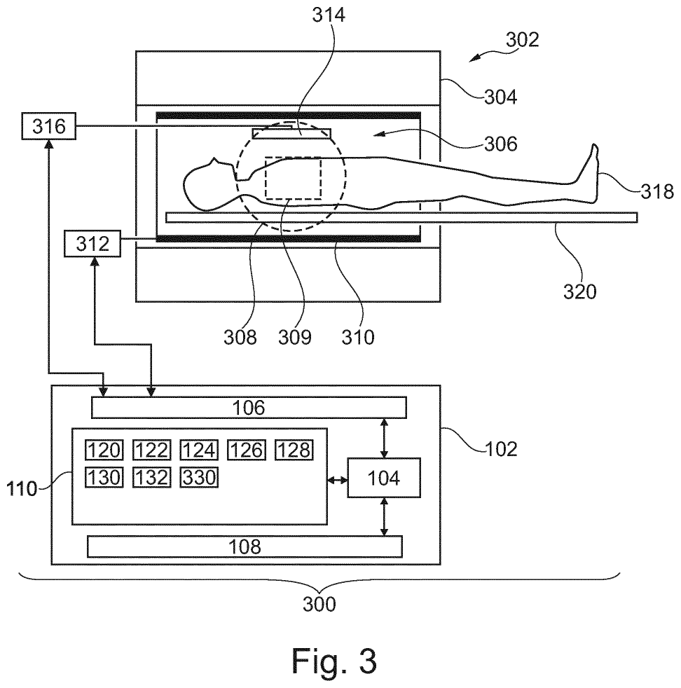

FIG. 3 illustrates a further example of a medical system 300. The medical system 300 depicted in FIG. 3 is similar to the medical system 100 depicted in FIG. 1 except that it additionally comprises a magnetic resonance imaging system 302 that is controlled by the computational system 104.

The magnetic resonance imaging system 302 comprises a magnet 304. The magnet 304 is a superconducting cylindrical type magnet with a bore 306 through it. The use of different types of magnets is also possible: for instance it is also possible to use both a split cylindrical magnet and a so called open magnet. A split cylindrical magnet is similar to a standard cylindrical magnet, except that the cryostat has been split into two sections to allow access to the iso-plane of the magnet, such magnets may for instance be used in conjunction with charged particle beam therapy. An open magnet has two magnet sections, one above the other with a space in-between that is large enough to receive a subject: the arrangement of the two sections area similar to that of a Helmholtz coil. Open magnets are popular, because the subject is less confined. Inside the cryostat of the cylindrical magnet there is a collection of superconducting coils.

Within the bore 306 of the cylindrical magnet 304 there is an imaging zone 308 where the magnetic field is strong and uniform enough to perform magnetic resonance imaging. A region of interest 309 is shown within the imaging zone 308. The magnetic resonance data that is acquired typically acquired for the region of interest. A subject 318 is shown as being supported by a subject support 320 such that at least a portion of the subject 318 is within the imaging zone 308 and the region of interest 309.

Within the bore 306 of the magnet there is also a set of magnetic field gradient coils 310 which is used for acquisition of preliminary magnetic resonance data to spatially encode magnetic spins within the imaging zone 308 of the magnet 304. The magnetic field gradient coils 310 connected to a magnetic field gradient coil power supply 312. The magnetic field gradient coils 310 are intended to be representative. Typically magnetic field gradient coils 310 contain three separate sets of coils for spatially encoding in three orthogonal spatial directions. A magnetic field gradient power supply supplies current to the magnetic field gradient coils. The current supplied to the magnetic field gradient coils 310 is controlled as a function of time and may be ramped or pulsed.

Adjacent to the imaging zone 308 is a radio-frequency coil 314 for manipulating the orientations of magnetic spins within the imaging zone 308 and for receiving radio transmissions from spins also within the imaging zone 308. The radio frequency antenna may contain multiple coil elements. The radio frequency antenna may also be referred to as a channel or antenna. The radio-frequency coil 314 is connected to a radio frequency transceiver 316. The radio-frequency coil 314 and radio frequency transceiver 316 may be replaced by separate transmit and receive coils and a separate transmitter and receiver. It is understood that the radio-frequency coil 314 and the radio frequency transceiver 316 are representative. The radio-frequency coil 314 is intended to also represent a dedicated transmit antenna and a dedicated receive antenna. Likewise the transceiver 316 may also represent a separate transmitter and receivers. The radio-frequency coil 314 may also have multiple receive/transmit elements and the radio frequency transceiver 316 may have multiple receive/transmit channels. For example if a parallel imaging technique such as SENSE is performed, the radio-frequency could 314 will have multiple coil elements.

The transceiver 316 and the gradient controller 312 are shown as being connected to the hardware interface 106 of the computer system 102.

The memory 110 is further shown as containing pulse sequence commands 330. The pulse sequence commands 330 are commands or data which may be converted into such commands that are configured for controlling the magnetic resonance imaging system 302 to acquire the undersampled k-space data 124 from the region of interest 309.

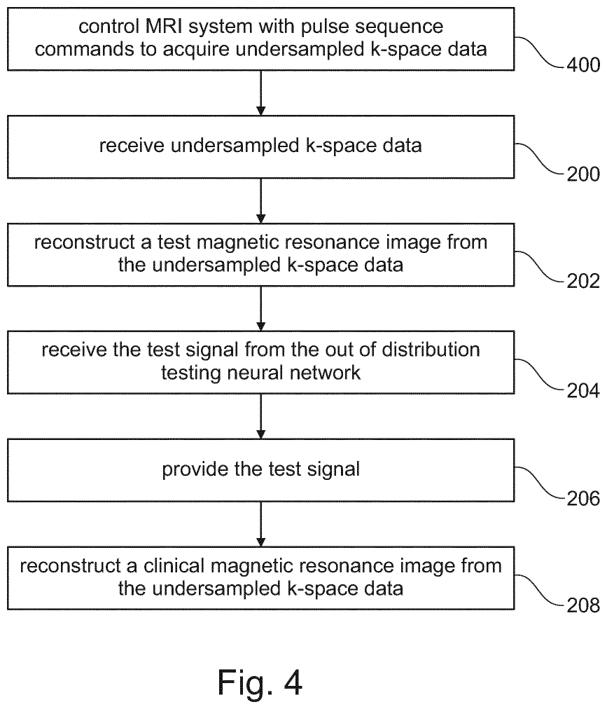

FIG. 4 shows a flowchart which illustrates a method of operating the medical system 300 of FIG. 3. First, in step 400, the magnetic resonance imaging system 302 is controlled with the pulse sequence commands 330 to acquire the undersampled k-space data 124. Next, the method proceeds to steps 200, 202, 204, 206 and 208 as is illustrated in FIG. 2.

In compressed sensing magnetic resonance imaging (CS-MRI), undersampling of k-space is performed to acquire images faster, improving on all KPIs of the quadruple aim. However, reconstructions of such undersampled data may suffer from poor quality and large number of artefacts if the acceleration rate is too high. Deep Learning based algorithms are proved to be effective for lowering reconstruction error, making grater undersampling rates possible.

However, the lack of control and hardly predictable behavior on previously unseen data is one of the main disadvantages of AI, compared to traditional algorithms. When the data to be processed is too dissimilar from the data used for training (out of distribution or OOD), it is often observed that Deep Learning solutions for medical imaging applications may produce realistic artefacts. Therefore, for a user of the AI-powered system it may not be possible to find and correct the mistake or avoid using the system in hard or ambiguous cases. This problem creates a large gap between experiments with neural networks and their actual application to real-world tasks.

Embodiments may provide a means to estimate whether a new input for a Deep Learning system is sufficiently similar to the training data using a discriminative model (out of distribution testing neural network 122) which is possibly trained in an adversarial manner. We utilize well known property of discriminator from Generative Adversarial Networks (GANs) to learn distribution of training data and apply it for OOD estimation. When being used, the model provides a test signal 128, which may be a probability that the object belongs to the training distribution or directly provides binary decision. This knowledge will also make possible to determine the feasibility of reconstruction of undersampled data without spending extra time and compute power on the reconstruction process. Therefore, this invention will enable and ease the application of Deep Learning solutions in a practical setting.

Examples may provide for a discriminative model to distinguish whether zero filled images are in-and-out of distribution. In order to do that we propose to utilize well known properties of the discriminator from Generative Adversarial Networks (GANs) to learn the distribution of training data and apply it for OOD estimation.

Such an approach solves several problems. First, they assume that either reconstruction or reconstruction network's features are somehow related with the distribution of the undersampled object, which is seldom true in practice. Second, both methods require one or more forward pass for the reconstruction network, such as Adaptive CS-Net, which might be computationally costly. Operating directly on the zero-filled images releases these requirements, making the OOD estimation both more computationally feasible and more interpretable.

In the simplest term, a GAN is used to generate realistic zero filled image (a fake testing magnetic resonance image 508). We adopt the discriminator (out of distribution testing neural network 122) of the GAN as an OOD scoring mechanism. In the next paragraph, we present a simplified approach to convey the general concept. In a later paragraph we show a more advanced and powerful generation mechanism.

In the initial setting, GAN samples a noise vector z using normal or uniform distribution and utilizes a deep neural network generator G to create an image Gₒᵤₜ. The discriminator D is added to distinguish whether the discriminator input is real or generated. Note that in this case Gₒᵤₜ is not the reconstruction, but a zero filled image. Therefore, the output of the discriminator, a value pp, estimates the probability for the input to be a realistic representation of the zero-filled images present in the training distribution. Since during the train time D perceives only the training data as real, it implicitly learns to distinguish objects from the training distribution, i.e., the zero-filled images used for training the reconstruction model, from objects from any other distributions. We therefore propose to use the discriminator D, and its output pp, as a way to compute the OOD score for the input.

Thus, the basic system may comprise one or more of the following elements:
z—the noise vector sampled from normal or uniform distribution
G—the generator model that creates realistic zero filled images from z
Gₒᵤₜ—the output of the reconstruction model G, i.e., a realistic zero filled image
p_{D}-probability of the input of the discriminator network D to be a real (not generated) object
L_{d}-loss of the discriminative model D. It is also used as a loss term for the generative model G

Undersampled image (UI)-inverse fast Fourier transform (iFFT) of element-wise multiplication product between fully sampled k-space and initial binary undersampling mask

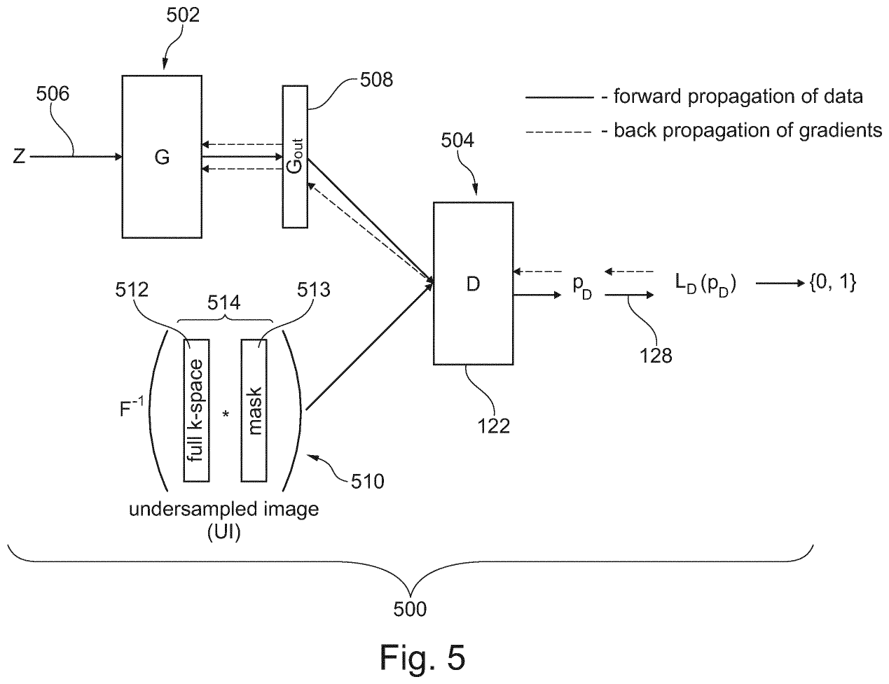

FIG. 5 illustrates one way of training the out of distribution testing neural network 122. FIG. 5 shows a generative adversarial neural network 500 that comprises a generator neural network 502 and a discriminator neural network 504. In this case, the discriminator neural network 504 is the out of distribution testing neural network 122. The generator neural network 502 is configured to receive a noise vector 506 and output a fake testing magnetic resonance image 508. The fake testing magnetic resonance image 508 is then input into the discriminator 504. During training it is known if the image 508 is real or not if the discriminator 504 guesses incorrectly then it is trained. If the generator neural network 502 fails to fool the discriminator 122 then it is trained. During training both the generator 502 and the discriminator 504 both become better together. Real data is also used for training the discriminator 504. In this case a training testing magnetic resonance image 510 is constructed from fully sampled k-space data 512. A mask 513 is used to construct simulated undersampled k-space data 514 by removing part of the fully sampled k-space data 512. This is then Fourier transformed to produce the training testing magnetic resonance image 510. During training the discriminator 504 can be tested using both the training testing magnetic resonance images 510 and the fake testing magnetic resonance images 508. The fully sampled k-space data 512 is used to construct the simulated undersampled k-space data 514. The space represented by the resulting images 510 and the simulated undersampled k-space data 514 represent the training distribution defined by the set of training data. The training data in this case are the pairs of simulated undersampled k-space data 514 and the training testing magnetic resonance images 510 developed from them. The fully sampled k-space data 512 can be used to construct training data for other neural networks such as neural networks which may be integrated into the compressed sensing reconstruction algorithm for generating the clinical magnetic resonance image.

First, the generative convolutional neural network G receives noise vector z from normal or uniform distribution. The goal of G is to produce a realistic zero-filled image and fool the discriminative convolutional neural network D 122. It produces Gₒᵤₜ 508, which is passed to D 122 along with the UI. The goal of D 122 is to correctly distinguish real UI 510 from the fake one 508 from G. D outputs p_{D}, which can be interpreted as a probability of Gₒᵤₜ to be real. After that, pp may be converted to the binary output. D 122 learns to predict correct outputs by minimizing LD. LD can be any classification loss, for example binary cross-entropy. G also gathers information from LD, but in contrast to D 122 its goal is to maximize it. Hence, G 502 and D 122 are optimized in an alternating manner to solve the adversarial minimax problem.

$${min}_{G} {max}_{D} {𝔼}_{UI \sim {p}_{train} ( UI )} [ log D ( UI ) ] + {𝔼}_{z \sim {p}_{z} ( z )} [ log ( 1 - D ( G ( z ) ) ) ] \qquad ( 1 )$$

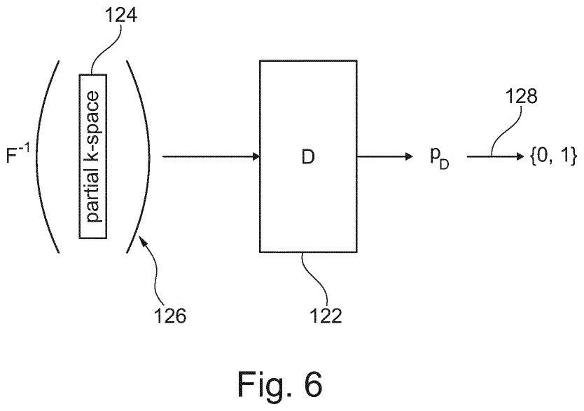

FIG. 6 illustrates the use of the out of distribution testing neural network 122. In this figure the partial k-space is the undersampled k-space data 124. This is then Fourier transformed to produce the test magnetic resonance image 126. This is then input into the out of distribution testing neural network 122 which is trained as a discriminator in the GAN 500 of FIG. 5. This then outputs the test signal 128. In this example the test signal 128 is a discreet 0 or 1. In other cases it could be a probability that is produced. FIG. 6 illustrates how the discriminative model can be used for OOD estimation on previously unseen data.

Partially sampled k-space is converted to the image using iFFT and passed to D. In one embodiment, p_{D} can be used as an estimation of probability of input data to be in-distribution. In another embodiment, p_{D} can be converted to the binary output using a threshold function to obtain a direct answer on whether the data belongs to the training distribution or not. Further these values can be used to either reject AI-based solution and revert to a classical one or to inform a user about potential incorrectness of the reconstruction and to propose reacquisition of the data.

Even though the proposed system solves the problem, in practice it may possibly suffer from the problems characterizing GANs training, namely mode collapse and non-convergence. In the first case, the system which lacks any supervision, can easily reach a local minimum where G produces limited varieties of samples. It prevents discriminator from generalizing well. In the second case the model parameters oscillate, destabilize and never converge. To eliminate these potential problems, we a form of self-supervision during training is described below. The following components are added to the proposed basic approach:
Missing information image (MII)-iFFT of element-wise multiplication product between fully sampled k-space and inverted initial binary undersampling mask
Lg-loss function of the reconstruction model G. It is computed as a distance between Gₒᵤₜ and UI

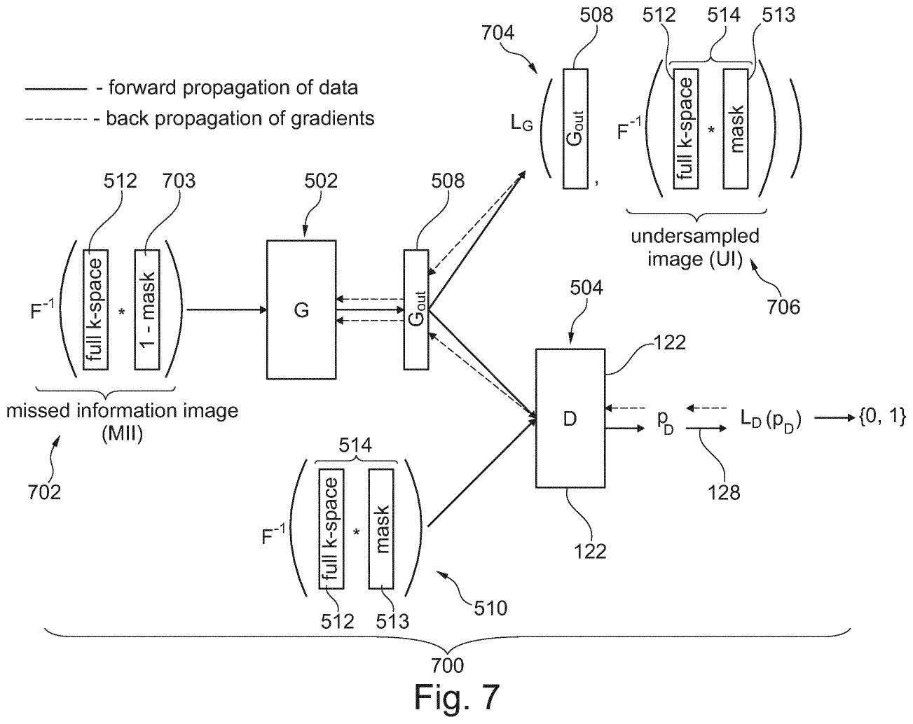

FIG. 7 shows an alternative generative adversarial neural network 700 that can be used for training the out of distribution testing neural network 122. This example is different in that the generator 502 is not input with a random or noise vector but instead a missed information image 702 is used instead. This is an image constructed from the fully sampled k-space data 512 using an alternative mask 703 which can either change the sampling to a different undersampling pattern or can cause some missed data so that the data is incomplete. This missed information image 702 is then input into the generator neural network and this is used to produce the fake testing magnetic resonance image 508. A loss function 704 is then constructed from the fake testing magnetic resonance image 508 and undersampled image 706. The undersampled image 706 is made from the undersampled k-space data 512 and the same mask 513 used to construct the testing magnetic resonance image 510. The fully sampled k-space data 512 and the mask 513 are used to provide simulated undersampled k-space data 514 which is then Fourier transformed to produce the undersampled image 706.

This example may be beneficial because during training it very rapidly produces realistic fake testing magnetic resonance images 508 and the out of distribution testing neural network 122 is trained very effectively.

FIG. 7 shows an overview of the modified training procedure. First, the generative convolutional neural network G 502 receives MII 702 as an input. Its goal is still to produce a realistic zero-filled image 508 and fool D 122. But now it learns to do that not only by maximizing L_{d}, but also by minimizing L_{g} between UI and output of the model Gₒᵤₜ. In practice Lg can be any loss for image-to-image tasks such as L₁, SSIM, MS-SSIM or combination of thereof. Second, Gₒᵤₜ along with UI is passed to D 122. The goal of D 122 is to correctly distinguish real UI from the fake one from G 502. Note that this is very similar to the basic approach presented above where the model is sampling from the noise vector z. In this case, we replace the generator with a more powerful preconditioner. Note that, despite this is a powerful and viable solution, other generators can be adopted.

Networks G 502 and D 122 are trained using (2) as an adversarial system but only D is used during the evaluation time to estimate an OOD score. It may seem like the system is solving the same problem as Adaptive CS-Net and only discriminative network D 122 is added. In fact, it does the opposite. Standard image reconstruction model tries to recover undersampling image UI. Our network G recovers the Missed Information Image, which is essential to train a sufficient discriminative model.

$${min}_{G} {max}_{D} {𝔼}_{UI \sim {p}_{train} ( UI )} [ log D ( UI ) ] + {𝔼}_{MII \sim {p}_{G} ( MII )} [ log ( 1 - D ( G ( MII ) ) ) ] \qquad ( 2 )$$

Examples may provide one or more of the following advantages: The method may be used directly on an input data before it goes through reconstruction chain. It may lower response time and reduce computational burden

The quality of the proposed system will get higher along with the increase of acceleration rate. Making the degree of undersampling bigger we increase the amount of information that MII contains, which will ease the training of the adversarial system and make it more stable during evaluation

It is possible to formally show that discriminative model from GAN learns the training data distribution. Therefore, the result of its work is a direct estimate of test sample to belong to the train distribution

Examples may possibly be used to estimate whether a new input for a Deep Learning system is sufficiently similar to the training data using discriminative model trained in an adversarial manner. We utilize well known property of discriminator from Generative Adversarial Networks (GANs) to learn distribution of training data and apply it for OOD estimation. This property is used to determine the feasibility of reconstruction of undersampled data without spending extra time and compute power on reconstruction process.

There are no restrictions on architectures of G 502 and D 122 except being convolutional neural networks, which can solve image-to-image and binary classification tasks respectively. However, usage of state-of-the-art models for reconstruction of undersampled MR data such as the Adaptive-CS-Net for G 502 may significantly increase the overall quality and reliability of the system.

In examples, the out of distribution testing neural network (G 502) may be implemented using a varied of neural network types. For example, a Resnet, dense net, or a basic CNN configured for image classification may be effectively used.

The generator neural network (D 122) may be implemented using a variety of neural network types. In general, neural networks configured for image proceeding may be effectively used. For example, an image processing neural network such as a U-net may be used.

Outputs from D 122 can be used in different ways depending on business needs and overall design of the reconstruction system. In one embodiment, p_{D}∈[0,1] can be used as a direct estimation of probability of input data to be in-distribution. It can be provided to the user “as is” to decide whether to reject AI-based solution and revert to a classical one or proceed with default Deep Learning model. In another embodiment the value of pd can be used by another smart system that will make a decision. In another embodiment, binary output of D can be used straight away. In this case, threshold that the model learned during train time will be applied.

Some examples may be applied to validate AI/Deep Learning based models for reconstruction of accelerated MR scans. In this case the approach will be as follows.

Train time:
Collect the training data (fully sampled raw MR datasets (fully sampled k-space data))
Apply reverse undersampling mask along with iFFT to the initial data to produce input data (MII)
Apply undersampling mask along with iFFT to the initial data (UI)
Train network G and D to solve (1) using MII and UI
Deploy D to the production environment
   System usage time:
Obtain an input data by scanning a patient with a desired level of undersampling
Compute pd and binary output of D
Utilize pd and binary output of D for validating the output of the AI (OOD or not OOD)

If the input data (test magnetic resonance image 126) is classified (by the test signal 128) as not OOD, do nothing. Else choose one or several steps from below:
Revert to other algorithms that do not suffer from the OOD problem (Compressed SENSE)
Inform the user or the manufacturer of the problem
Take corrective actions such a rescan for a MR acquisition

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measured cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

### REFERENCE SIGNS LIST

100 medical system
102 computer
104 computational system
106 optional hardware interface
108 optional user interface
110 memory
120 machine executable instructions
122 out of distribution testing neural network
124 undersampled k-space data
126 test magnetic resonance image
128 test signal
130 compressed sensing magnetic resonance imaging reconstruction algorithm
132 clinical magnetic resonance image
200 receive undersampled k-space data descriptive of a region of interest of a subject
202 reconstruct the test magnetic resonance image from the undersampled k-space data
204 receive the test signal in response to inputting the test magnetic resonance image into the out of distribution testing neural network
206 provide the test signal
208 reconstruct a clinical magnetic resonance image from the undersampled k-space data according using a compressed sensing magnetic resonance imaging reconstruction algorithm if the test signal indicates that the test magnetic resonance image is within the training distribution
300 medical system
302 magnetic resonance imaging system
304 magnet
306 bore of magnet
308 imaging zone
309 region of interest
310 magnetic field gradient coils
312 magnetic field gradient coil power supply
314 radio-frequency coil
   transceiver
318 subject
320 subject support
330 pulse sequence commands
400 acquire the undersampled k-space data by controlling the magnetic resonance
   imaging system with the pulse sequence commands
500 generative adversarial neural network
502 generator neural network
504 discriminator neural network
506 noise vector
508 fake testing magnetic resonance image
510 training testing magnetic resonance image
512 fully sampled k-space data
513 mask
514 simulated undersampled k-space data
700 generative adversarial neural network
702 missed information image
703 alternative mask
704 loss function
706 under sampled image

1. A medical system comprising:
a memory storing machine executable instructions;
a computational system, wherein execution of the machine executable instructions causes the computational system to:
receive a test magnetic resonance image reconstructed from undersampled k-space data;
receive a test signal in response to causing an input of the test magnetic resonance image into an out of distribution testing neural network, wherein the test neural network is configured for outputting the test signal in response to receiving the test magnetic resonance image, wherein the test signal is descriptive if the test magnetic resonance image is within a training distribution defined by a set of training data; and
provide the test signal.

2. The medical system of claim 1, wherein execution of the machine executable instructions further causes the computational system to cause a reconstruction of a clinical magnetic resonance image from the undersampled k-space data according using a compressed sensing magnetic resonance imaging reconstruction algorithm if the test signal indicates that the test magnetic resonance image is within the training distribution.

3. The medical system of claim 2, wherein the compressed sensing magnetic resonance imaging reconstruction algorithm is configured for reconstructing the clinical magnetic resonance image iteratively using an image processing neural network.

4. The medical system of claim 3, wherein the image processing neural network is configured as the following:
a denoising filter for denoising an intermediate image between each iteration; and
as an image compression algorithm.

5. The medical system of claim 2, wherein the compressed sensing magnetic resonance imaging reconstruction algorithm is a numerical image reconstruction algorithm configured for finding solutions to underdetermined linear systems descriptive of a reconstruction of the clinical magnetic resonance image from the undersampled k-space data.

6. The medical system of claim 2, wherein the compressed sensing magnetic resonance imaging reconstruction algorithm comprises an image reconstruction neural network configured for reconstructing the clinical magnetic resonance image from the undersampled k-space data at each stage of an iterative compressed sensing algorithm.

7. The medical system of claim 1, wherein the out of distribution testing neural network is trained as a discriminator neural network in a generative adversarial network using the training data.

8. The medical system of claim 7, wherein the generative adversarial network comprises a generative neural network configured for generating simulated images in response to receiving a noise distribution.

9. The medical system of claim 7, wherein the generative adversarial network comprises a generative neural network configured for generating simulated images in response to receiving a simulated test image.

10. The medical system of claim 1, wherein the test magnetic resonance image is reconstructed from the undersampled k-space data using a Fourier transform.

11. The medical system of claim 1, wherein the memory further contains pulse sequence commands configured to control a magnetic resonance imaging system to acquire the undersampled k-space data from the region of interest, wherein execution of the machine executable instructions further causes the computational system to acquire the undersampled k-space data by controlling the magnetic resonance imaging system with the pulse sequence commands.

12. The medical system of claim 1, wherein execution of the machine executable instructions further causes the computational system to perform the following if the test signal indicates that the test magnetic resonance image is outside of the training distribution:
provide a warning signal;
request a reacquisition of the undersampled k-space data;
request a reconstruction of the clinical magnetic resonance image using a purely numerical reconstruction algorithm;
control the magnetic resonance imaging system to continue acquisition of the undersampled k-space data;
reconstruct the test magnetic resonance image from undersampled k-space data descriptive of a region of interest of a subject; and
receive the test signal in response to inputting the test magnetic resonance image into the out of distribution testing neural network.

13. The medical system of claim 1, wherein the training data for the out of distribution testing neural network comprises simulated undersampled k-space data constructed from fully sampled k-space data and simulated test magnetic resonance images reconstructed from the simulated undersampled k-space data.

14. A method of operating a medical system, wherein the method comprises:
receiving a test magnetic resonance image reconstructed from undersampled k-space data;
receiving a test signal in response to inputting the test magnetic resonance image into an out of distribution testing neural network, wherein the test neural network is configured for outputting a test signal in response to receiving the test magnetic resonance image, wherein the test signal is descriptive if the test magnetic resonance image is within a training distribution defined by a set of training data; and
providing the test signal.

15. A computer program comprising machine executable instructions for execution by a computational system, wherein execution of the machine executable instructions causes the computational system to:
receive a test magnetic resonance image reconstructed from the undersampled k-space data;
receive a test signal in response to inputting the test magnetic resonance image into an out of distribution testing neural network, wherein the test neural network is configured for outputting the test signal in response to receiving the test magnetic resonance image, wherein the test signal is descriptive if the test magnetic resonance image is within a training distribution defined by a set of training data; and
provide the test signal.
